(19) United States
(12) Patent Application Publication
(10) Pub. No.: US 2026/0206639 A1
(43) Pub. Date: Jul. 16, 2026

(54) SEMICONDUCTOR ARRANGEMENT WITH AT LEAST ONE SEMICONDUCTOR ELEMENT

(71) Applicant: Siemens Aktiengesellschaft, 80333 München (DE)

(72) Inventors: STEPHAN NEUGEBAUER, Erlangen (DE); OLIVER RAAB, Ortenberg (DE); CHRISTIAN RADÜGE, Nürnberg (DE); STEFAN STEGMEIER, München (DE); CLAUS FLORIAN WAGNER, Nürnberg (DE); MICHAEL WOITON, Nürnberg (DE)

(73) Assignee: Siemens Aktiengesellschaft, 80333 München (DE)

(21) Appl. No.: 19/134,035

(22) PCT Filed: Oct. 12, 2023
(86) PCT No.: PCT/EP2023/078383

§ 371 Date: May 29, 2025

(30) Foreign Application Priority Data
Nov. 30, 2022 (EP) 22210598.3

(51) Int. Cl. H10W 76/47; H10W 40/22; H10W 40/25; H10W 72/60; H10W 76/05; H10W 76/45; H10W 90/00

(52) U.S. Cl. CPC H10W 76/47; H10W 72/634; H10W 76/05; H10W 76/45; H10W 90/754; H10W 90/764; H10W 40/226; H10W 40/255

(57) ABSTRACT

A semiconductor arrangement, in particular a power semiconductor arrangement for a converter, includes a closed housing, a semiconductor element arranged in the housing, and a free-flowing material at least partially filling the housing and directly contacting the semiconductor element. The free-flowing material contains electrically insulating particles. A circuit carrier is arranged in the housing, and the semiconductor element is connected by a force-fit connection to the circuit carrier.

The invention relates to a semiconductor arrangement, in particular a power semiconductor arrangement for a converter, with at least one semiconductor element.

The invention further relates to a converter with at least one such semiconductor arrangement.

Moreover, the invention relates to a method for producing a semiconductor arrangement, in particular a power semiconductor arrangement for a converter, with at least one semiconductor element.

The invention also relates to the use of a free-flowing material, which contains electrically insulating particles, for filling a housing of a semiconductor arrangement.

Such semiconductor arrangements are used in a converter, for example. A “converter” means a rectifier, an inverter, a transducer, or a direct current converter, for example, Such semiconductor arrangements usually comprise a housing, in which at least one semiconductor element is arranged. Such a semiconductor element may be a transistor, for example. A soft potting compound, in particular a silicone potting compound, is usually provided inside the housing to protect the at least one semiconductor element.

The publication WO 2022/033745 A1 describes a power module with at least one power unit, which comprises at least one power semiconductor and a substrate, wherein the at least one power unit is at least partially surrounded by a housing. The housing is filled with a soft potting compound, in particular with a silicone potting compound.

Environmental aspects are also becoming increasingly important in electronics development. In particular, improved recyclability is becoming the focus. Recyclability and repair costs are improved, for example, by eliminating the need for material-bonded connections, which can be produced by soldering, sintering, or welding.

The publication EP 3 926 670 A1 describes a power semiconductor module with at least one power semiconductor element. In order to reduce the required installation space of the power semiconductor module and to increase its service life, it is proposed that the at least one power semiconductor element is in an electrically insulating and thermally conductive connection with a cooling element via a dielectric material layer, wherein the dielectric material layer rests flat on a surface of the cooling element and has a force-fit connection to the cooling element by means of a first force acting orthogonally to the surface of the cooling element.

The publication WO 2018/046165 A1 describes a power module with a semiconductor component to be contacted on the top and bottom, wherein the semiconductor component can be electrically contacted on the top by a leadframe matrix using contact pressure.

A soft potting compound is very difficult to remove, for example, during recycling processes. Against this background, it is an object of the present invention to improve the recyclability of a semiconductor arrangement.

This object is achieved according to the invention by a semiconductor arrangement, in particular a power semiconductor arrangement for a converter, with at least one semiconductor element, wherein the at least one semiconductor element is arranged in a housing, in particular a closed housing, wherein the housing is at least partially filled with a free-flowing material, which contains electrically insulating particles and is in direct contact with the at least one semiconductor element.

Furthermore, the object is achieved according to the invention by a power converter with at least one such semiconductor arrangement.

Moreover, the object is achieved according to the invention by methods for producing a semiconductor arrangement, in particular a power semiconductor arrangement for a converter, with at least one semiconductor element, wherein the at least one semiconductor element is arranged in a housing, wherein the housing is at least partially filled with a free-flowing material, which contains electrically insulating particles, in such a way that the free-flowing material is in direct contact with the at least one semiconductor element, wherein the housing is closed in an additional step.

Moreover, the object is achieved according to the invention by the use of a free-flowing material, which contains electrically insulating particles, for filling a housing of a semiconductor arrangement, In which at least one semiconductor element is arranged, wherein the filling is effected in such a way that the free-flowing material is in direct contact with the at least one semiconductor element.

The advantages and preferred embodiments listed below with respect to the semiconductor arrangement can be transferred analogously to the converter, the production method, and the use.

The invention is based on the idea of improving the recyclability of a semiconductor arrangement by replacing a commonly used soft potting compound with a free-flowing material, which contains electrically insulating particles. A housing of the semiconductor arrangement, in which at least one semiconductor element is arranged, is at least partially filled with the free-flowing material in such a way that the semiconductor element is in direct contact with the free-flowing material. In particular, the semiconductor element is at least partially surrounded by the free-flowing material. The free-flowing material can contain, for example, quartz sand, carbonate sand, gypsum sand, silicate, but also organic free-flowing substances, for example, polymers, siloxanes. The free-flowing material can be removed far more easily due to its sand-like structure, particularly in comparison to the commonly used soft potting compound. Simple disassembly for repair, refurbishment, or recycling is facilitated by filling with such a free-flowing material. This also saves on materials and energy-intensive production processes.

Another embodiment variant provides for the electrically insulating particles of the free-flowing material to have a grain size in the range from 0.01 mm to 0.6 mm, in particular 0.1 mm to 0.4 mm. In particular, an average grain size is in the range from 0.2 mm to 0.3 mm. Such a grain size minimizes air gaps and achieves an adequate insulating effect, for example. In particular, gaps can be minimized with a bimodal or higher mix of the free-flowing material, which also improves the insulating effect.

Another embodiment variant provides for the electrically insulating particles of the free-flowing material to contain a metal oxide. For example, the electrically insulating particles contain aluminum and/or titanium oxide, glass, mica and/or ceramic particles. A good insulating effect is achieved using such metal oxides. Using inorganic electrically insulating particles, such as aluminum oxide sand, gives the semiconductor arrangement increased explosion protection, because inorganic substances cause significantly fewer, in particular hardly any, explosion gases; thus, no carbon dioxide or water is produced, and pressure forces can be absorbed more effectively.

Another embodiment variant provides for the electrically insulating particles of the free-flowing material to have a sharply broken surface, in particular a jagged surface. Such a surface extends creepage distances, particularly in comparison to a spherical structure.

Another embodiment variant provides for the free-flowing material to be filled with a meltable insulating material, in particular a wax. High-melting paraffins or other waxes, in particular with a melting point above 100° C., are potential options here. For example, gaps are filled with the meltable insulating material, wherein the material creeps into the particle gaps when melted, replacing the air and hardening when cooled. This approach substantially increases the module's breakdown voltage. In particular, an insulating material that can be melted multiple times, such as a wax, is relatively thin in its melted state and, for example, easy to remove during a recycling process. Paraffins or other waxes are also biodegradable and/or reusable.

Another embodiment variant provides for the free-flowing material to be filled with an insulating fluid. Such insulating fluids include fluorinated hydrocarbons, for example, 3M Novec. A sludge can be formed by such an insulating fluid, which is easily removable during disassembly for repair, refurbishment, or recycling and Improves the insulating effect. Additionally, the insulating fluid can be an electrically insulating gas, which fills the gaps of the free-flowing material to achieve an even greater insulating effect.

Another embodiment variant provides for the insulating fluid to contain a phase change material, whereby heat peaks can be mitigated.

Another embodiment variant provides for a circuit carrier to be arranged in the housing, wherein the semiconductor element has a force-fit connection to the circuit carrier, in particular by means of a pressure contact. Such a pressure contact can be embodied as a busbar, for example. Alternatively, a spring, a screw, and/or a bracket can be used for a force-fit connection of the semiconductor element. A circuit carrier can be a substrate, for example, In particular a direct copper bonded (DCB) substrate. Such a force-fit connection of the semiconductor element is detachable and easy to remove when disassembling for repair, refurbishment, or recycling, particularly in combination with the filling of a free-flowing material.

Another embodiment variant provides for the housing to comprise a heat sink on which the circuit carrier rests flat, wherein the circuit carrier has a force-fit connection to the heat sink. Such a force-fit connection can be achieved by pressure, among other things, and makes disassembly easier, for example, for recycling.

Another embodiment variant provides for the circuit carrier to have a detachable and thermally conductive connection to the heat sink, in particular by means of an oil layer. Such an oil layer creates a detachable connection between the circuit carrier and heat sink and compensates for the surface roughness of the surface of the heat sink or of the circuit carrier. In particular, a thermally conductive oil for the oil layer improves the thermal coupling of the circuit carrier and heat sink.

Another embodiment variant provides for the semiconductor element to have at least one contact on a side facing away from the circuit carrier, wherein the at least one contact is surrounded by a plastic frame, in particular a glued-on or pressed-on plastic frame. Such a plastic frame improves an insulated section, in particular for HV power modules.

Another embodiment variant provides that a metal contacting element rests on at least one of the contacts of the semiconductor element and is pressed by means of a pressure contact to achieve force-fit contacting with the semiconductor element. For example, the metal contacting element is embodied as a small copper plate or small molybdenum plate, which has a thickness in the range from 10 μm to 250 μm, in particular 25 μm to 250 μm. The metal contacting element acts as a pressure buffer, which distributes pressure forces, for example, from the pressure contact, preventing the occurrence of pressure peaks in the sensitive semiconductor element. Such an arrangement of a pressure buffer with a force-fit connection makes disassembly easier, for example, for recycling.

The invention is described in more detail and explained below using the exemplary embodiments presented in the figures.

It is shown in:

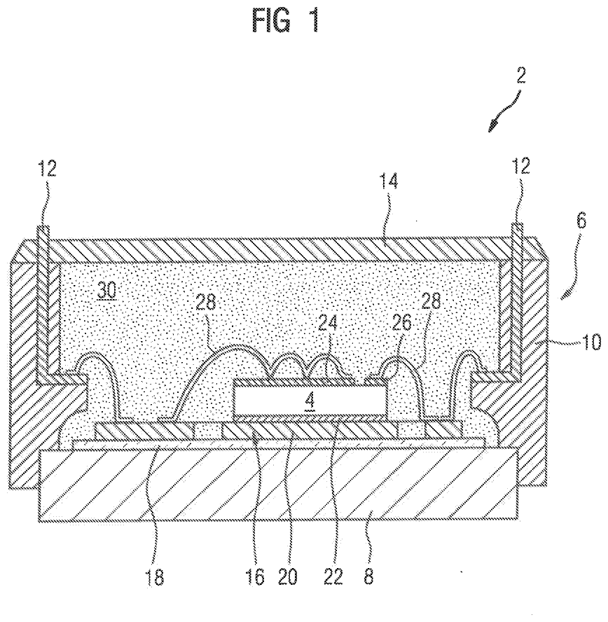

FIG. 1 a schematic sectional representation of a first embodiment variant of a semiconductor arrangement,

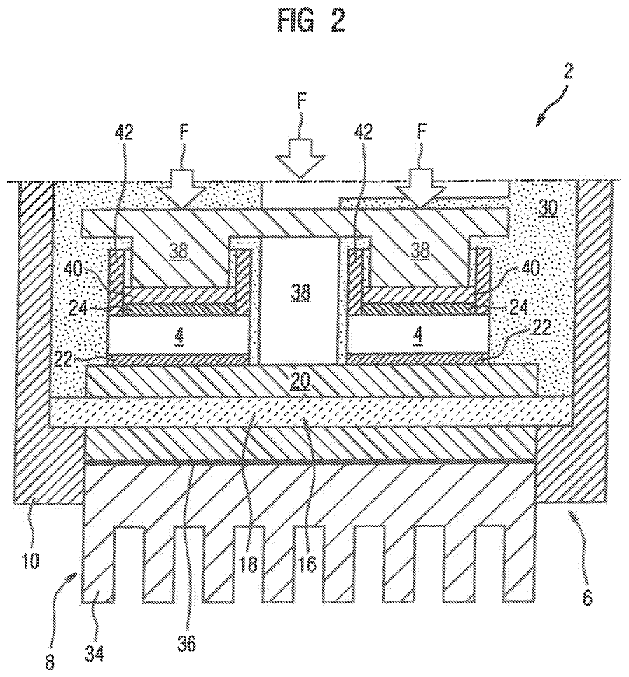

FIG. 2 a schematic sectional representation of a second embodiment variant of a semiconductor arrangement,

FIG. 3 an enlarged schematic representation of a first embodiment variant of a free-flowing material,

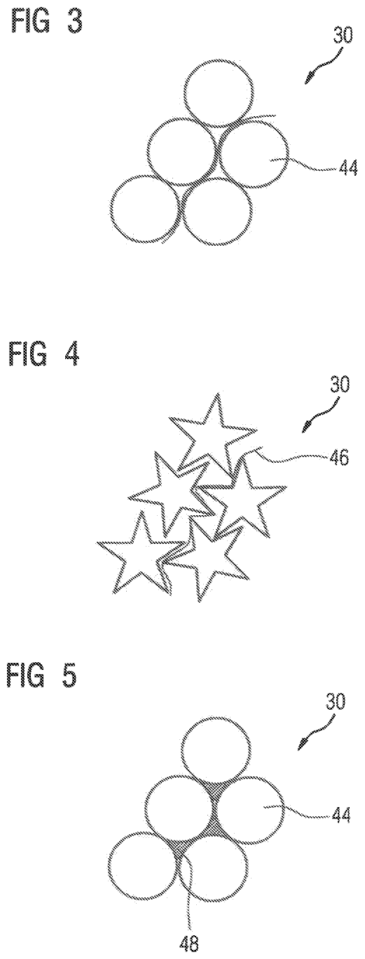

FIG. 4 an enlarged schematic representation of a second embodiment variant of a free-flowing material,

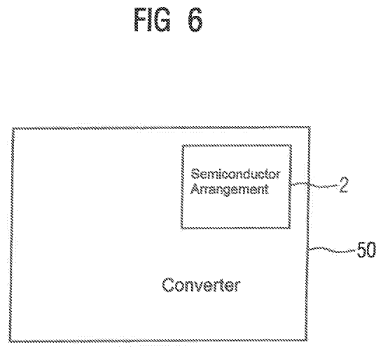

FIG. 5 an enlarged schematic representation of a third embodiment variant of a free-flowing material,

FIG. 6 a schematic representation of a converter.

The exemplary embodiments explained below are preferred embodiment variants of the invention. In the exemplary embodiments, the described components of the embodiment variants each represent individual features of the invention that are to be considered independently of each other, which also each develop the invention independently of each other and thus should be viewed as part of the invention, both individually or in a combination other than that shown. Moreover, the described embodiment variants can also be supplemented with the other features of the invention that have already been described.

The same reference characters have the same meaning in the various figures.

FIG. 1 shows a schematic sectional representation of a first embodiment variant of a semiconductor arrangement 2 with a semiconductor element 4, which is arranged in a closed housing 6. For example, the semiconductor element 4 is embodied as a vertical transistor, in particular as an IGBT or vertical SIC MOSFET. The housing 6 comprises a metal heat sink 8, a housing frame 10 with multiple pins 12 and a housing cover 14. The housing frame 10 and the housing cover 14 are made from a plastic, for example, wherein the pins 12 are molded or pressed into the housing frame 10. The heat sink 8, which acts as a base plate, is made from copper, aluminum, or one of their alloys, for example. A circuit carrier 16 is connected flat to the heat sink 8. For example, the circuit carrier 16 comprises a dielectric material layer 18, which contains in particular aluminum oxide, aluminum nitride, or an organic electrically insulating and thermally conductive material, and metallization 20, which contains copper, gold, molybdenum, silver, or one of their alloys, for example. The dielectric material layer 18 can be connected to the heat sink by means of pressing or an adhesive bond. Alternatively, the circuit carrier 16 can be embodied as a substrate, in particular a direct copper bonded (DCB) substrate, which is soldered to the heat sink 8, for example,

The semiconductor element 4 has a first power contact 22, in particular a collector contact, and a second power contact 24 on an opposite side, in particular an emitter contact, and a control contact 26, in particular a gate contact. The first power contact 22 of the semiconductor element 4 has, for example, a material-bonded connection to the metallization 20 of the circuit carrier 16. The material-bonded connection of the semiconductor element 4 and the circuit carrier 16 can be achieved by soldering and/or sintering, for example. The second power contact 24 and control contact 26 arranged on a side of the semiconductor element 4 facing away from the circuit carrier 16 are each connected to the metallization 20 of the circuit carrier 16 by wiring means 28, wherein the metallization 20 is wired to the pins 12 of the housing 6. In this manner, the contacts 22, 24, 26 of the semiconductor element 4 are led out of the housing 6 and can be contacted electroconductively from outside by means of the pins 12. The wiring means 28 is embodied, for example, as bonding wires or bonding ribbons, which are welded in particular by means of ultrasonic wire bonding.

The housing 6 is filled, for example, completely, with a free-flowing material 30, which contains electrically insulating particles, is in direct contact with the semiconductor element (4), and partially surrounds this. The free-flowing material 30 can contain a free-flowing sand, for example, which contains electrically insulating particles from a metal oxide, for example, aluminum oxide. Additionally or alternatively, the free-flowing material 30 can contain other inorganic substances, for example, quartz sand, carbonate sand, gypsum sand, silicate, but also organic free-flowing substances, for example, polymers, siloxanes. In particular, the electrically insulating particles of the free-flowing material 30 have a grain size in the range from 0.01 mm to 0.6 mm, in particular 0.1 mm to 0.4 mm. An average grain size can be from 0.2 mm to 0.3 mm. The free-flowing material 30 replaces a commonly used casting compound in the semiconductor arrangement 2, which is produced, for example, from a silicone insulating material that is difficult to remove. The free-flowing material 30 can easily be removed after the housing 6 is opened, so that the components in the housing 6 are freely accessible for recycling and repair processes.

Optionally, the sand filling can be layered or otherwise refined with the free-flowing material 30, wherein the electrically insulating particles have, for example, different densities for improved separability. The purpose of layering can be, for example, to use more cost-efficient filling materials in areas with uncritical, electrical fields or to realize additional functions, such as flame protection, arc quenching, or heat buffering.

FIG. 2 shows a schematic sectional representation of a second embodiment variant of a semiconductor arrangement 2 with two semiconductor elements 4, for example, which are arranged in a closed housing 6. The housing 6 comprises a metal heat sink 8, a housing frame 10, and a housing cover, which is not shown in FIG. 2 for reasons of clarity. A circuit carrier 16, which is, for example, embodied as a DCB substrate and has a dielectric material layer 18 with two-sided metallization 20, rests flat on the heat sink 8. The heat sink has ribs 34 on a side facing away from the DCB substrate. An oil layer 36 creates a detachable and thermally conductive connection between the DCB substrate and the heat sink. The thermally conductive oil of the oil layer 36 compensates for the surface roughness of the surfaces of the heat sink 8 or of the circuit carrier 16, thus improving the thermal coupling.

There is a metal contacting element 40 on each of the second power contacts 24 of the semiconductor elements 4. Additionally or alternatively, such metal contacting elements 40 can be arranged between the circuit carrier 16 and the first power contact 22 of the semiconductor elements 4. For example, the metal contacting elements 40 are embodied as small copper plates or small molybdenum plates, which each have a thickness in the range from 25 μm to 250 μm. Alternatively, the metal contacting elements 40 are connected to the respective semiconductor element 4 through material-bonding, for example, through soldering or sintering. Additionally, the metal contacting elements 40 can be sprayed on by means of a thermal spraying process, in particular in the form of copper and/or molybdenum particles.

By means of pressure contacts 38, which are contacted via the metal contacting elements 40 to the second power contacts 24 of the semiconductor elements 4, the semiconductor elements 4 have a force-fit and detachable connection to the metallization 20 of the circuit carrier 16. The pressure contacts 38 are embodied as busbars in FIG. 2. For example, the busbars are made from copper or a copper alloy. Additionally or alternatively, the pressure contacts 38 can have a spring contact. A force F acting orthogonally to the surface of the circuit carrier 16 is transferred via the busbars; this force F fixes the semiconductor elements 4. The housing 6 is, as shown in FIG. 1, filled with a free-flowing material 30, which contains electrically insulating particles and is in direct contact with the semiconductor elements 4 and partially surrounds them. For example, the free-flowing material 30 contains quartz sand and/or aluminum oxide sand. Optionally, the free-flowing material 30 is covered in the area of the housing cover wholly or partially by a film, which is pressed against the free-flowing material 30, for example, by an elastic intermediate element, in particular a polymer foam. Alternatively, the elastic intermediate element is directly pressed against the free-flowing material 30, preventing trickling and thus the emergence of cavities. Redensification is achieved at the same time, which increases the insulating effect and thus has a positive effect on operational reliability.

For HV power modules in particular, the second power contacts 24 of the semiconductor elements 4 are surrounded by a glued-on or pressed-on plastic frame 42, in order to improve an insulated section. Alternatively, the plastic frame 42 can be applied additively, by means of a dispensing or 3D printing process, for example. To prevent air pockets when the free-flowing material 30 is added, holes can be drilled in the pressure contacts 38, for example. The further embodiment of the semiconductor arrangement 2 in FIG. 2 corresponds to the embodiment in FIG. 1.

FIG. 3 shows an enlarged schematic representation of a first embodiment variant of a free-flowing material 30, which contains a sand, which has electrically insulating particles 44 with a spherical structure and low grain size in the range from 0.01 mm to 0.6 mm, in particular 0.1 mm to 0,4 mm, which makes adding easier and reduces the likelihood of air pockets. For example, the free-flowing material 30 contains quartz sand, in particular fuse sand. The further embodiment of the free-flowing material 30 corresponds to that in FIG. 1.

FIG. 4 shows an enlarged schematic representation of a second embodiment variant of a free-flowing material 30, which has electrically insulating particles 44 with a sharply broken, Ideally jagged, surface. Such a surface composition extends creepage paths 46, particularly compared to a spherical structure. The further embodiment of the free-flowing material 30 in FIG. 4 corresponds to that in FIG. 3.

FIG. 5 shows an enlarged schematic representation of a third embodiment variant of a free-flowing material 30, which is filled with a meltable insulating material, in particular with a wax. High-melting paraffins or other waxes, in particular with a melting point above 100° C., are options for this. Additionally or alternatively, the free-flowing material 30 is filled with an insulating fluid, which contains fluorinated hydrocarbons, for example, 3M Novec. The Insulating fluid causes sludge to form. The insulating fluid can be embodied as phase change material, in order to mitigate heat peaks. To guarantee improved partial discharge resistance, and thus the service life of the semiconductor arrangement 2, the free-flowing material 30 can contain a material with a high resistance to partial discharge, for example, mica. The further embodiment of the free-flowing material 30 in FIG. 5 corresponds to that in FIG. 3. The particles 44 of the free-flowing material 30 in FIG. 5 can at least partially have a sharply broken, ideally jagged, surface, as shown in FIG. 4.

FIG. 6 shows a schematic representation of a converter 50, which comprises a semiconductor arrangement 2. The converter 50 can comprise more than one semiconductor arrangement 2.

The invention can be summarized as a semiconductor arrangement 2, in particular a power semiconductor arrangement for a converter 50, with at least one semiconductor element 4, wherein the at least one semiconductor element 4 is arranged in a housing 6, in particular a closed housing 6. In order to improve the recyclability of a semiconductor arrangement 2, it is proposed that the housing 6 is at least partially filled with a free-flowing material 30, which contains electrically Insulating particles 44 and is in direct contact with the at least one semiconductor element 4.

1.-17. (canceled)

18. A semiconductor arrangement, in particular a power semiconductor arrangement for a converter, the semiconductor arrangement comprising:
a closed housing;
a semiconductor element arranged in the housing;
a free-flowing material at least partially filling the housing and directly contacting the semiconductor element, the free-flowing material containing electrically insulating particles; and
a circuit carrier arranged in the housing,
wherein the semiconductor element is connected by a force-fit connection to the circuit carrier.

19. The semiconductor arrangement of claim 18, further comprising a pressure contact designed to effect the force-fit connection of the semiconductor element to the circuit carrier.

20. The semiconductor arrangement of claim 18, wherein the electrically insulating particles of the free-flowing material have a grain size in a range from 0.01 mm to 0.6 mm, in particular in a range from 0.1 mm to 0.4 mm.

21. The semiconductor arrangement of claim 18, wherein the electrically insulating particles of the free-flowing material contain a metal oxide.

22. The semiconductor arrangement of claim 18, wherein the electrically insulating particles of the free-flowing material have a sharply broken surface, in particular a jagged surface.

23. The semiconductor arrangement of claim 18, wherein the free-flowing material is filled with a meltable insulating material, in particular a wax.

24. The semiconductor arrangement of claim 18, wherein the free-flowing material is filled with an insulating fluid.

25. The semiconductor arrangement of claim 24, wherein the Insulating fluid contains a phase change material.

26. The semiconductor arrangement of claim 18, wherein the housing comprises a heat sink, the circuit carrier resting flat on the heat sink and connected to the heat sink by a force-fit connection.

27. The semiconductor arrangement of claim 26, wherein the circuit carrier has a detachable and thermally conductive connection to the heat sink.

28. The semiconductor arrangement of claim 27, further comprising an oil layer effecting the detachable and thermally conductive connection to the heat sink.

29. The semiconductor arrangement of claim 18, wherein the semiconductor element comprises a contact on a side facing away from the circuit carrier, the semiconductor arrangement further comprising a plastic frame designed to surround the contact.

30. The semiconductor arrangement of claim 29, wherein the plastic frame is a glued-on or pressed-on plastic frame.

31. The semiconductor arrangement of claim 18, wherein the semiconductor element comprises a plurality of said contact, the semiconductor arrangement further comprising a metal contacting element resting on at least one of the plurality of said contact of the semiconductor element and pressed by the pressure contact to achieve a force-fit contacting with the semiconductor element.

32. A converter, comprising the semiconductor arrangement of claim 18.

33. A method for producing a semiconductor arrangement, in particular a power semiconductor arrangement for a converter, the method comprising:
arranging a semiconductor element and a circuit carrier in a housing;
connecting the semiconductor element by a force-fit connection to the circuit carrier;
at least partially filling the housing with a free-flowing material, which contains electrically insulating particles in such a way that the free-flowing material is in direct contact with the semiconductor element; and
closing the housing.

34. The method of claim 33, wherein the semiconductor element is connected by the force-fit connection to the circuit carrier by a pressure contact.

35. The method of claim 33, further comprising filling the free-flowing material with a meltable insulating material, in particular a wax.

36. The method of claim 33, further comprising filling the free-flowing material with an insulating fluid.

37. A method for disassembly, for repair, for refurbishment or for recycling of a semiconductor arrangement produced by the method of claim 36, the method comprising:
opening the housing;
detaching the force-fit connection of the semiconductor element; and
removing the free-flowing material.
